(19) United States
(12) Patent Application Publication
(10) Pub. No.: US 2025/0149220 A1
(43) Pub. Date: May 8, 2025

(54) FIXATION STRUCTURE, AND ELECTRONIC UNIT

(71) Applicant: TDK Corporation, Tokyo (JP)

(72) Inventors: Junpei SAWAYAMA, Tokyo (JP); Kouji KANEKO, Tokyo (JP)

(73) Assignee: TDK Corporation, Tokyo (JP)

(21) Appl. No.: 18/835,434

(22) PCT Filed: Mar. 31, 2022
(86) PCT No.: PCT/JP2022/016590

§ 371 Date: Aug. 2, 2024

(51) Int. Cl. H01F 7/02; H01F 27/02; H01F 27/06

(52) U.S. Cl. CPC H01F 7/0221; H01F 27/06; H01F 27/02

(57) ABSTRACT

A fixation structure includes: a structure; a first magnetic component and a second magnetic component fixed to the structure and facing each other in a first direction; and a spacer member disposed between the first magnetic component and the second magnetic component, in which a gap in the first direction is formed to absorb an error in arrangement of the first magnetic component and the second magnetic component in the first direction between the spacer member and the structure.

### TECHNICAL FIELD

The present disclosure relates to a fixation structure and an electronic unit.

### BACKGROUND ART

Conventionally, in order to maintain an appropriate gap between a plurality of spaced away magnetic components, it is known that the magnetic components are fixed to a structure after a resin spacer member is disposed (see Patent Literature 1). In this fixation structure, positioning of the magnetic components and the spacer member during assembly is performed by providing the spacer member with a guide shape.

### CITATION LIST

### Patent Literature

Patent Literature 1: Japanese Unexamined Patent Publication No. 2012-169425

### SUMMARY OF INVENTION

### Technical Problem

Here, when an error (variation) occurs in the magnetic component, the structure, the spacer member, and the like during manufacturing or assembly, an error (variation) may occur in arrangement in a direction in which a pair of magnetic components and the spacer member face each other. Such an error (variation) affects the fixation structure during assembly or after assembly, and there arises a problem that designed characteristics cannot be obtained.

An object of the present disclosure is to provide a fixation structure capable of suppressing an influence of an error in arrangement of the magnetic component.

### Solution to Problem

A fixation structure according to an aspect of the present disclosure includes: a structure; a first magnetic component and a second magnetic component fixed to the structure and facing each other in a first direction; and a spacer member disposed between the first magnetic component and the second magnetic component, and the spacer member and the structure are spaced away from each other.

The fixation structure according to an aspect of the present disclosure includes: the first magnetic component and the second magnetic component fixed to the structure and facing each other in the first direction; and the spacer member disposed between the first magnetic component and the second magnetic component. Therefore, a resin spacer member can maintain a gap of an appropriate size between the first magnetic component and the second magnetic member. Here, the spacer member and the structure are spaced away from each other. Therefore, even if an error occurs in arrangement of the first magnetic component and the second magnetic component, a gap between the spacer member and the structure can absorb the error. As described above, the influence of the error in the arrangement of the magnetic component can be suppressed.

The fixation structure includes a first positioning mechanism configured to position the spacer member with respect to the structure in a direction orthogonal to the first direction, and in this case, the spacer member can be easily positioned in the direction orthogonal to the first direction by the first positioning mechanism.

The first positioning mechanism may include: a first projecting portion formed on one of the spacer member and the structure and extending in the first direction; and an insertion portion formed on the other of the spacer member and the structure and for inserting the first projecting portion in the insertion portion. In this case, when the spacer member is assembled to the structure, the spacer member can be easily positioned in the direction orthogonal to the first direction only by inserting the first projecting portion into the insertion portion.

The fixation structure may include a second positioning mechanism configured to position another component other than the first magnetic component and the second magnetic component and the spacer member. In this case, not only positioning between the spacer member and the structure but also positioning between the spacer member and the other component can be performed.

The structure may include a second projecting portion projecting in the first direction toward the spacer member, and a gap between the spacer member and the structure may be formed between the second projecting portion and the spacer member. In this case, the size of the gap can be easily adjusted by adjusting a projection amount of the second projecting portion.

An electronic unit according to an aspect of the present disclosure includes the fixation structure described above.

According to the electronic unit, it is possible to obtain the same functions and effects as those of the fixation structure described above.

### Advantageous Effects of Invention

According to the present disclosure, it is possible to provide the fixation structure capable of suppressing the influence of the error in the arrangement of the magnetic component.

### BRIEF DESCRIPTION OF DRAWINGS

FIG. 1 is a perspective view illustrating a fixation structure and an electronic unit according to the present embodiment of the present disclosure.

FIG. 2 is a perspective view illustrating the fixation structure and the electronic unit according to the present embodiment of the present disclosure.

FIG. 3 is a cross-sectional view taken along line III-III of FIG. 1.

FIG. 4 is a cross-sectional view taken along line IV-IV of FIG. 1.

FIG. 5 is a cross-sectional view taken along line V-V of FIG. 2.

FIG. 6(a) is an enlarged view of a portion indicated by a region E1 in FIG. 5, and FIG. 6(b) is an enlarged view of a portion indicated by a region E2 in FIG. 5.

### DESCRIPTION OF EMBODIMENTS

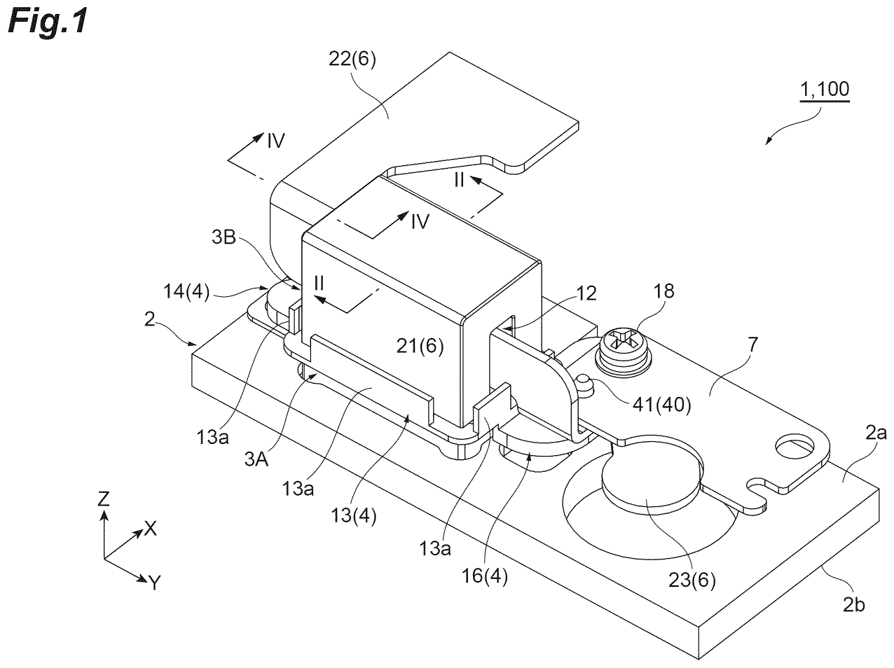

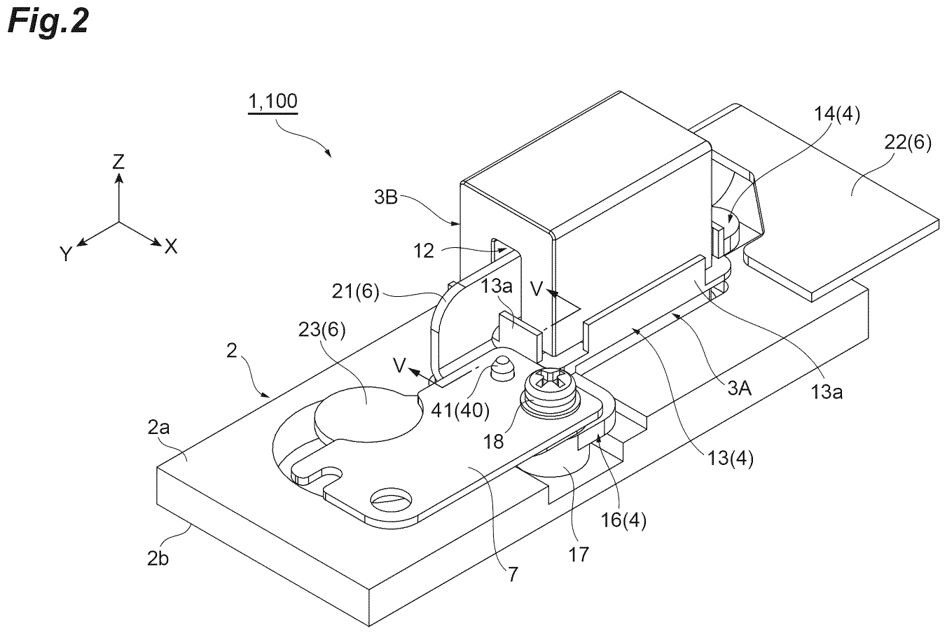

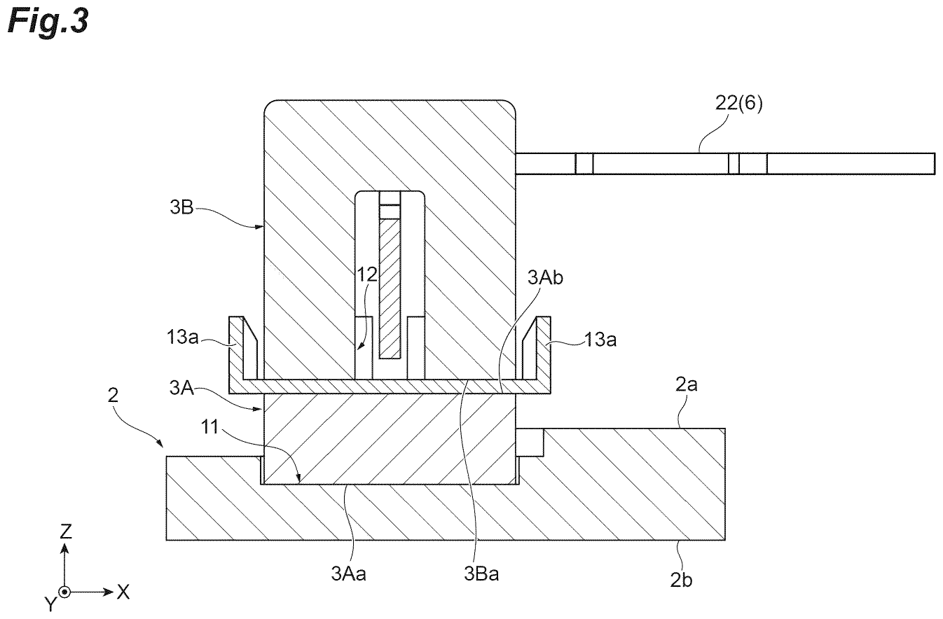

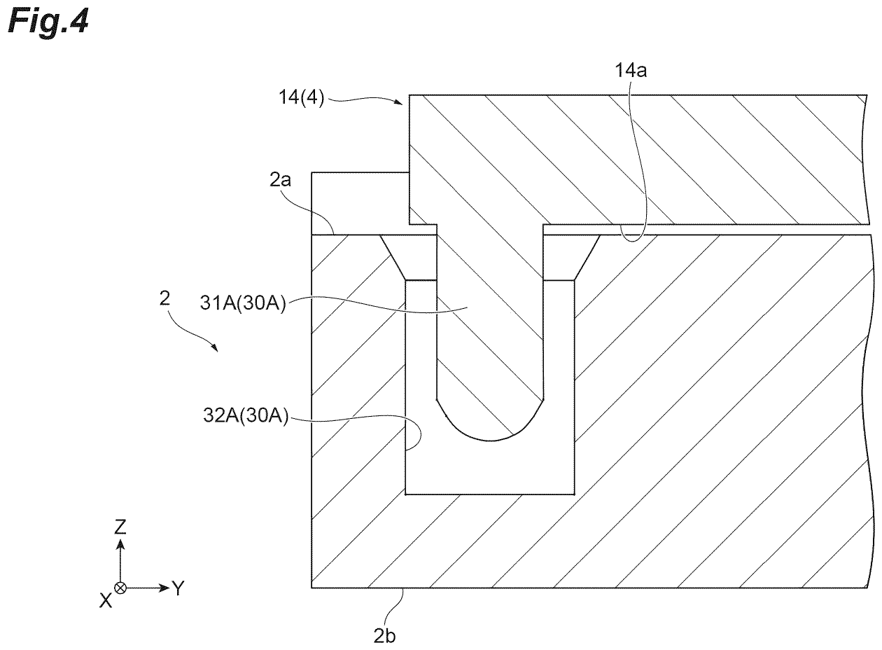

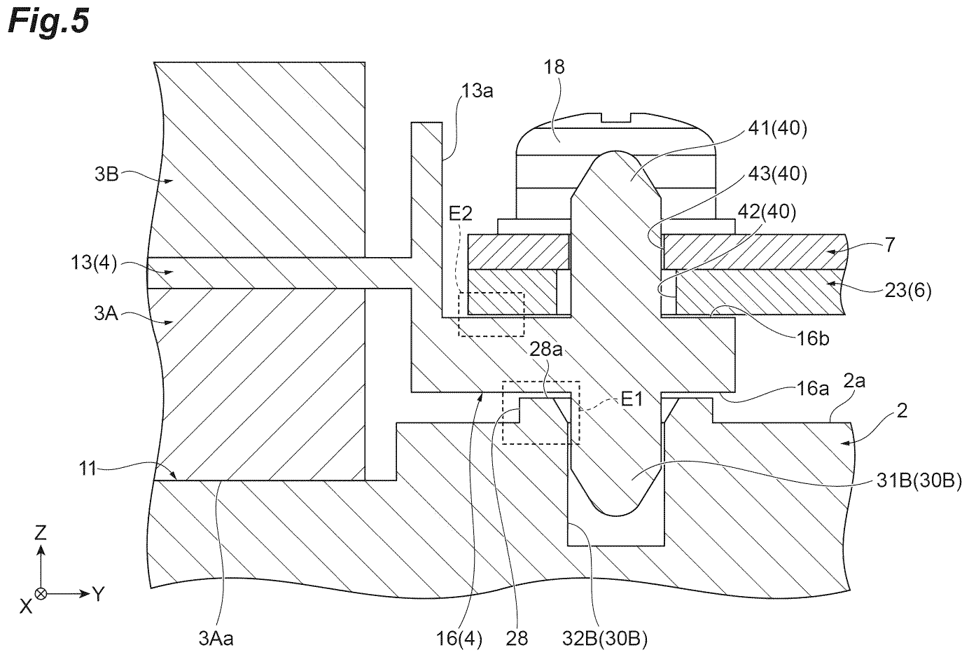

A fixation structure 1 and an electronic unit 100 according to an embodiment of the present disclosure will be described with reference to FIGS. 1 to 5. FIGS. 1 and 2 are plan views illustrating the fixation structure 1 and the electronic unit 100 according to the present embodiment of the present disclosure. FIG. 3 is a cross-sectional view taken along line III-III of FIG. 1. FIG. 4 is a cross-sectional view taken along line IV-IV of FIG. 1. FIG. 5 is a cross-sectional view taken along line V-V of FIG. 2.

As illustrated in FIGS. 1 and 2, the fixation structure 1 is a structure that fixes a first core 3A (a first magnetic component) and a second core 3B (a second magnetic component) to a base plate 2 (a structure). The fixation structure 1 is applied to, for example, the electronic unit 100 configured by housing a substrate, an electronic component, and the like in an internal space of a box-shaped housing body. Examples of the electronic unit 100 include a DC/DC converter, a charger, and an engine control unit (ECU). In FIGS. 1 and 2, a part of such an electronic unit 100 is illustrated. The electronic unit 100 includes the fixation structure 1 at least partially. The fixation structure 1 includes the base plate 2, the first core 3A, the second core 3B, a spacer member 4, a bus bar 6 (another component), and a substrate 7 (another component).

As illustrated in FIGS. 1 and 2, the base plate 2 is a structure that supports the first core 3A, the second core 3B, the spacer member 4, the bus bar 6, and the substrate 7. The base plate 2 is a member constituting a housing body that houses the above-described electronic unit. The base plate 2 has a main surface 2a that supports components of the electronic unit, and a main surface 2b that constitutes an outer surface of the housing body. The base plate 2 has a projecting portion and a groove on the main surface 2a that supports the components, and a specific structure thereof will be described later together with other components. Note that the following description may be made using XYZ coordinates. The X-axis direction and the Y-axis direction are directions orthogonal to each other, and are planar directions in which the base plate 2 extends. The Z-axis direction is a direction orthogonal to the X-axis direction and the Y-axis, and is a thickness direction of the base plate 2. In the Z-axis direction, the main surface 2a side is a positive side, and the main surface 2b side is a negative side. One side in the X-axis direction and the Y-axis direction is defined as a positive side, and the other side is defined as a negative side.

The first core 3A is an I-shaped core. The first core 3A is disposed on the main surface 2a of the base plate 2. The first core 3A is disposed on the negative side in the Z-axis direction with respect to the second core 3B. The first core 3A has a rectangular parallelepiped shape whose longitudinal direction is the Y-axis direction. As illustrated in FIGS. 3 and 5, a recess 11 for positioning the first core 3A in the X-axis direction and the Y-axis direction at the time of assembling the first core 3A is formed in the main surface 2a of the base plate 2. A main surface 3Aa on the negative side in the Z-axis direction of the first core 3A is disposed in the recess 11 so as to be in contact with a bottom surface of the recess 11. Thus, the first core 3A is positioned in the Z-axis direction with respect to the base plate 2 and is thermally connected. At this time, four side surfaces of the first core 3A face four side surfaces of the recess 11 with a slight gap therebetween. Thus, the first core 3A is positioned in the X-axis direction and the Y-axis direction with respect to the base plate 2.

As illustrated in FIGS. 1 and 2, the second core 3B is a U-shaped core. The second core 3B is disposed at a position on the positive side in the Z-axis direction with respect to the first core 3A. The second core 3B has a substantially rectangular parallelepiped shape whose longitudinal direction is the Y-axis direction. Further, the second core 3B has an inverted U-shape when viewed from the Y-axis direction. As illustrated in FIG. 3, the second core 3B has an opening 12 extending from a main surface 3Ba on the negative side in the Z-axis direction to the positive side in the Z-axis direction. The opening 12 extends in a constant cross-sectional shape in the Y-axis direction. The main surface 3Ba on the negative side in the Z-axis direction of the second core 3B and a main surface 3Ab on the positive side in the Z-axis direction of the first core 3A face each other in the Z-axis direction while being spaced away from each other with the spacer member 4 interposed therebetween.

In the present embodiment, the first core 3A is the I-shaped core, and the second core 3B is the U-shaped core, but the cores are not limited to this combination of shapes, and may be a combination of U/U, E/I, or

E/E cores.

As illustrated in FIGS. 1 and 2, the spacer member 4 is a member made of a material having insulating and nonmagnetic properties and disposed between the first core 3A and the second core 3B. The spacer member 4 includes a main body portion 13 and protruding portions 14 and 16.

The main body portion 13 is a portion that forms a gap between the first core 3A and the second core 3B. The main body portion 13 has a rectangular plate-like shape extending parallel to the XY plane. The main body portion 13 is interposed between the first core 3A and the second core 3B so as to be in contact with the main surface 3Ab on the positive side in the Z-axis direction of the first core 3A and the main surface 3Ba on the negative side in the Z-axis direction of the second core 3B (see FIG. 3). Thus, a constant core gap corresponding to a thickness of the main body portion 13 is formed between the first core 3A and the second core 3B. Thus, the second core 3B is magnetically coupled to the first core 3A via the resin spacer member 4. Note that four edges of the main body portion 13 respectively protrude from four edges of the cores 3A and 3B. Further, side wall portions 13a projecting toward the positive side in the Z-axis direction are provided at four edge portions of the main body portion 13. The four side wall portions 13a face four side surfaces of the second core 3B (see FIGS. 3 and 5). Thus, the second core 3B is positioned in the X-axis direction and the Y-axis direction by the four side wall portions 13a.

In the present embodiment, the side wall portion 13a projects toward the positive side in the Z-axis direction at the four edge portions of the main body portion 13, but may project toward the negative side. Thus, the first core 3A is positioned in the X-axis direction and the Y-axis direction together with the recess 11 of the base plate 2 by the four side wall portions 13a.

The protruding portion 14 is a portion protruding from the edge portion of the main body portion 13 on the negative side in the Y-axis direction toward the negative side in the Y-axis direction. The protruding portion 14 has a plate-like shape extending parallel to the XY plane so as to face the main surface 2a of the base plate in the Z-axis direction. The protruding portion 14 constitutes a part of a first positioning mechanism described later.

The protruding portion 16 is a portion protruding from the edge portion of the main body portion 13 on the positive side in the Y-axis direction toward the positive side in the Y-axis direction. The protruding portion 16 has a plate-like shape extending parallel to the XY plane so as to face the main surface 2a of the base plate in the Z-axis direction. The protruding portion 16 constitutes the part of the first positioning mechanism and a part of a second positioning mechanism described later. Further, the protruding portion 16 has a boss 17 extending toward the negative side in the Z-axis direction. The boss 17 is a portion that receives a bolt 18 for fastening the bus bar 6 and the substrate 7 to the protruding portion 16.

The bus bar 6 is a conductive member for allowing a current to flow. The bus bar 6 includes a first portion 21 passing through the opening 12 of the second core 3B, a second portion 22 provided on the negative side in the Y-axis direction with respect to the first portion 21, and a third portion 23 provided on the positive side in the Y-axis direction with respect to the first portion 21. The first portion 21 has a plate-like shape extending parallel to the YZ plane and extends in the Y-axis direction so as to pass through the opening 12. The second portion 22 extends toward the positive side in the X-axis direction from an edge portion on the positive side in the Z-axis direction of an end portion on the negative side in the Y-axis direction of the first portion 21. The second portion 22 has a plate-like shape extending parallel to the XY plane. The third portion 23 extends toward the positive side in the X-axis direction from an edge portion on the negative side in the Z-axis direction of an end portion on the positive side in the Y-axis direction of the first portion 21. The third portion 23 has a plate-like shape extending parallel to the XY plane. The third portion 23 is disposed to overlap the protruding portion 16 of the spacer member 4 on the positive side in the Z-axis direction. In addition, the third portion 23 is electrically connected to a terminal block (not illustrated) or the like.

The substrate 7 is a circuit board that forms an electric circuit. The substrate 7 has a plate-like shape extending parallel to the XY plane. The substrate 7 is disposed to overlap the third portion 23 of the bus bar 6 on the positive side in the Z-axis direction. The substrate 7 is fastened together with the third portion 23 of the bus bar 6 to the protruding portion 16 of the spacer member 4 by means of the bolt 18.

As illustrated in FIGS. 4 and 5, the spacer member 4 and the base plate 2 include positioning mechanisms 30A and 30B (the first positioning mechanism) that position the spacer member 4 with respect to the base plate 2 in the X-axis direction and the Y-axis direction. That is, the fixation structure 1 includes the positioning mechanisms 30A and 30B at two locations.

As illustrated in FIG. 4, the positioning mechanism 30A is provided at a position of the protruding portion 14 on the negative side in the Y-axis direction of the spacer member 4. The positioning mechanism 30A includes a projecting portion 31A and an insertion portion 32A. The projecting portion 31A is formed on the protruding portion 14 of the spacer member 4 and extends to the negative side in the Z-axis direction. The projecting portion 31A projects from a main surface 14a on the negative side in the Z-axis direction of the protruding portion 14 toward the negative side in the Z-axis direction. The projecting portion 31A has a columnar shape. The insertion portion 32A is a portion formed in the base plate 2 and into which the projecting portion 31A is inserted. The insertion portion 32A is formed at the same position as the projecting portion 31A (the first projecting portion) in the X-axis direction and the Y-axis direction on the main surface 2a of the base plate 2. The insertion portion 32A is formed by a hole (a recess) portion having a circular cross-section in accordance with the shape of the projecting portion 31A extending from the main surface 2a to the negative side in the Z-axis direction. An inner diameter of the insertion portion 32A is larger than a diameter of the projecting portion 31A. In a positioning state, an end portion on the negative side in the Z-axis direction of the insertion portion 32A is disposed at a position spaced apart from a bottom surface of the insertion portion 32A toward the positive side in the Z-axis direction.

In the present embodiment, both the projecting portion 31A and the insertion portion 32A have circular cross-sections, but the present invention is not limited thereto. As long as a cross-sectional shape of the insertion portion 32A enables insertion of the projecting portion 31A and secures a clearance satisfying a function as the positioning mechanism, shapes of both may be combined in various ways.

As illustrated in FIG. 5, the positioning mechanism 30B is provided at a position of the protruding portion 16 on the positive side in the Y-axis direction of the spacer member 4. The positioning mechanism 30B includes a projecting portion 31B and an insertion portion 32B. The projecting portion 31B is formed on the protruding portion 16 of the spacer member 4 and extends to the negative side in the Z-axis direction. The projecting portion 31B projects from a main surface 16a on the negative side in the Z-axis direction of the protruding portion 16 toward the negative side in the Z-axis direction. The projecting portion 31B has a columnar shape.

The base plate 2 has a projecting portion 28 projecting in the Z-axis direction toward the spacer member 4. The projecting portion 28 is formed at the same position as the projecting portion 31B in the X-axis direction and the Y-axis direction on the main surface 2a of the base plate 2. The projecting portion 28 has a columnar shape extending from the main surface 2a toward the positive side in the Z-axis direction. The insertion portion 32B is a portion formed in the projecting portion 28 of the base plate 2 and into which the projecting portion 31B is inserted. The insertion portion 32B is formed by a hole (a recess) portion having a circular cross-section in accordance with the shape of the projecting portion 31B extending from an end surface 28a on the positive side in the Z-axis direction of the projecting portion 28 to the negative side in the Z-axis direction. An inner diameter of the insertion portion 32B is larger than a diameter of the projecting portion 31B. In the positioning state, an end portion on the negative side in the Z-axis direction of the insertion portion 32B is disposed at a position spaced apart from a bottom surface of the insertion portion 32B toward the positive side in the Z-axis direction. Combination of shapes of the projecting portion 31B and the insertion portion 32B is the same as that of the projecting portion 31B and the insertion portion 32B. Further, whether or not the projecting portion 28 is placed is determined by a positional relationship between the base plate 2 and the spacer member 4 in the Z-axis direction, and a height thereof is determined when the projecting portion 28 is placed. The shape of the projecting portion 28 is not necessarily the columnar shape, and the projecting portion 28 can have various shapes.

With this configuration, the spacer member 4 is positioned with respect to the base plate 2 within a range of a gap (a clearance) formed in a radial direction between the projecting portion 31A and the insertion portion 32A and within a range of a gap (a clearance) formed in a radial direction between the projecting portion 31B and the insertion portion 32B. Further, the positioning mechanisms 30A and 30B at two locations function as a rotation stopper of the spacer member 4 with respect to the base plate 2.

As illustrated in FIG. 5, the fixation structure 1 includes a positioning mechanism 40 (the second positioning mechanism) that positions other components other than the first core 3A and the second core 3B. In the present embodiment, the bus bar 6 and the substrate 7 are positioned as the other components. As illustrated in FIG. 5, the positioning mechanism 40 is provided at a position of the protruding portion 16 on the positive side in the Y-axis direction of the spacer member 4. The positioning mechanism 40 includes a projecting portion 41 and two insertion portions 42 and 43. The projecting portion 41 is formed at a position concentric with the projecting portion 31B of the protruding portion 16 of the spacer member 4 and extends toward the positive side in the Z-axis direction. The projecting portion 41 projects from a main surface 16b on the positive side in the Z-axis direction of the protruding portion 16 toward the positive side in the Z-axis direction. The projecting portion 41 has a columnar shape. One insertion portion 42 is a portion formed in the third portion 23 of the bus bar 6 and into which the projecting portion 41 is inserted. The other insertion portion 43 is a portion formed in the substrate 7 and into which the projecting portion 41 is inserted. The insertion portions 42 and 43 are formed at the same positions as the projecting portion 41 in the X-axis direction and the Y-axis direction so as to penetrate the bus bar 6 and the substrate 7. Inner diameters of the insertion portions 42 and 43 are larger than a diameter of the projecting portion 41. The projecting portion 41 projects toward the positive side in the Z-axis direction from the bus bar 6 and the substrate 7 (see FIGS. 1 and 2).

In the present embodiment, the projecting portion 41 is formed at the position concentric with the projecting portion 31B, but it is not necessary to be at the concentric position, and may be shifted from the concentric position. Further, combination of shapes of the projecting portion 41 and the two insertion portions 42 and 43 is the same as that of the projecting portion 31B and the insertion portion 32B.

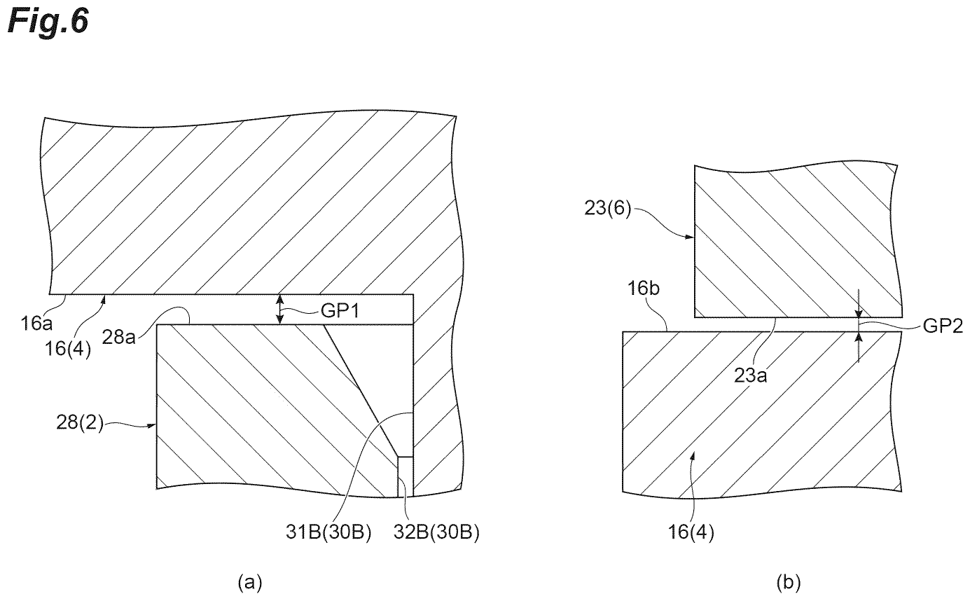

Here, FIG. 6(a) is an enlarged cross-sectional view of a portion indicated by a region E1 in FIG. 5. As illustrated in FIG. 6(a), a gap GP1 in the Z-axis direction for absorbing an error in arrangement of the first core 3A and the second core 3B in the Z-axis direction is formed between the spacer member 4 and the base plate 2. In the present embodiment, the gap GP1 in the Z-axis direction is formed between the projecting portion 28 and the spacer member 4. The gap GP1 is formed between the end surface 28a on the positive side in the Z-axis direction of the projecting portion 28 and the main surface 16a of the protruding portion 16 of the spacer member 4 on the negative side in the Z-axis direction. The gap GP1 is a gap at a position closest to the base plate 2 in the Z-axis direction in the spacer member 4.

FIG. 6(b) is an enlarged cross-sectional view of a portion indicated by a region E2 in FIG. 5. As illustrated in FIG. 6(b), a gap GP2 in the Z-axis direction for absorbing the error in the arrangement of the first core 3A and the second core 3B in the Z-axis direction is formed between the spacer member 4 and the bus bar 6. In the present embodiment, the gap GP2 in the Z-axis direction is formed between the main surface 16b on the positive side in the Z-axis direction of the protruding portion 16 of the spacer member 4 and a main surface 16b on the negative side in the Z-axis direction of the third portion 23 of the bus bar 6. The gap GP2 is a gap at a position closest to the bus bar 6 in the Z-axis direction in the spacer member 4.

As described above, in the protruding portion 16 of the spacer member 4, the gap GP1 is formed on the negative side in the Z-axis direction, and the gap GP2 is formed on the positive side in the Z-axis direction. The size of the gap GP1 is set to such a size that the main surface 16a does not come into contact with the end surface 28a even if an error occurs in a depth of the recess 11, a thickness of the first core 3A, a shape of the spacer member 4, and the like, and the position of the main surface 16a of the spacer member 4 is shifted to the negative side in the Z-axis direction from a position of a design value. The size of the gap GP2 is set to such a size that the main surface 16b does not come into contact with the end surface 23a even if an error occurs in the depth of the recess 11, the thickness of the first core 3A, the shape of the spacer member 4, and the like, and the position of the main surface 16b of the spacer member 4 is shifted to the positive side in the Z-axis direction from a position of a design value.

Functions and effects of the fixation structure 1 according to the present embodiment will be described.

First, a fixation structure according to a comparative example will be described. In the fixation structure according to the comparative example, the gap GP1 is not formed, and the spacer member 4 (the main surface 16a) and the base plate 2 (the end surface 28a) are in contact with each other. Meanwhile, in a magnetic component that is solidified and manufactured through a process of “compounding magnetic powder, mixing, press compression molding, and sintering”, the external dimensions vary depending on the compounding, mixing, compression, and sintering conditions of the powder. In an application of the present application, the spacer member 4 is inserted between combined cores, and an air gap is formed by a thickness of the spacer member 4. When the spacer member 4 is in contact with the base plate 2 as in the comparative example, for example, when the thickness of the first core 3A is smaller than the design value due to variation, or when the bottom surface of the recess 11 is deeper than the design value, a gap is generated between the first core 3A and the spacer member 4, and the air gap is larger than the design value. Conversely, when the thickness of the first core 3A is larger than the design value due to variation, or when the bottom surface of the recess 11 is shallower than the design value, there arises a problem that unnecessary stress acts on both the first core 3A and the spacer member 4 in the vicinity of the contact portion, and for example, the core is chipped or the spacer member 4 is deformed.

The fixation structure 1 according to the present embodiment includes: the first core 3A and the second core 3B fixed to the base plate 2 and facing each other in the Z-axis direction; and the spacer member 4 disposed between the first core 3A and the second core 3B. Therefore, an appropriate gap length can be maintained between the first core 3A and the second core 3B by the resin spacer member 4. Here, the spacer member 4 and the base plate 2 are spaced away from each other. Therefore, the gap (the clearance) GP1 in the Z-axis direction for absorbing variations in dimensions and arrangement of the first core 3A and the second core 3B in the Z-axis direction is formed between the spacer member 4 and the base plate 2. Therefore, even if the arrangement of the first core 3A and the second core 3B varies in the Z-axis direction, the gap (the clearance) GP1 in the Z-axis direction can absorb the variation. For example, it is assumed that the thickness or height of the first core 3A is smaller than the design value due to the variation, or the bottom surface of the recess 11 is deeper than the design value, and the spacer member 4 is disposed to be lowered to the negative side in the Z-axis direction as a whole from the design value. Even in such a case, shift of the position of the spacer member 4 from the design value is absorbed by the gap (the clearance) GP1. Conversely, it is assumed that the thickness or height of the first core 3A is larger than the design value due to the variation, or the bottom surface of the recess 11 is shallower than the design value, and the spacer member 4 is disposed to rise to the positive side in the Z-axis direction as a whole from the design value. Even in such a case, shift of the position of the spacer member 4 from the design value is absorbed by the gap (the clearance) GP1. As described above, an influence of the variation in the arrangement of the cores 3A and 3B in the Z-axis direction can be suppressed, and as a result, the gap between the cores can be managed by the thickness of the resin spacer.

The fixation structure 1 may include the positioning mechanisms 30A and 30B that position the spacer member 4 with respect to the base plate 2 in a direction (the XY-axis direction) orthogonal to the Z-axis direction. The spacer member 4 can be easily positioned in the XY-axis direction orthogonal to the Z-axis direction by the positioning mechanisms 30A and 30B.

The positioning mechanisms 30A and 30B may include the projecting portions 31A and 31B formed on the spacer member 4 and extending in the Z-axis direction, and the insertion portions 32A and 32B formed on the base plate 2 and into which the projecting portions 31A and 31B are inserted. In this case, when the spacer member 4 is assembled to the base plate 2, the spacer member 4 can be easily positioned in the XY-axis direction orthogonal to the Z-axis direction only by inserting the projecting portions 31A and 31B into the insertion portions 32A and 32B.

The fixation structure 1 may include the positioning mechanism 40 that positions the bus bar 6 and the substrate 7, which are the other components other than the first core 3A and the second core 3B, and the spacer member 4. In this case, not only positioning between the spacer member 4 and the base plate 2 but also positioning between the spacer member 4 and the bus bar 6 and the substrate 7 can be performed.

The base plate 2 may include the projecting portion 28 projecting in the Z-axis direction toward the spacer member 4, and the gap GP1 in the Z-axis direction between the spacer member 4 and the base plate 2 may be formed between the projecting portion 28 and the spacer member 4. In this case, the size of the gap GP1 can be easily adjusted by adjusting a projection amount of the projecting portion 28.

The electronic unit 100 according to the present embodiment includes the fixation structure 1 described above.

According to the electronic unit 100, it is possible to obtain the same functions and effects as those of the fixation structure 1 described above.

The present disclosure is not limited to the above-described embodiments.

In the above-described embodiments, in the positioning mechanisms 30A and 30B, the projecting portions 31A and 31B are formed in the spacer member 4, and the insertion portions 32A and 32B are formed in the base plate 2. Instead of this, the insertion portion may be formed in the spacer member 4, and the projecting portion may be formed in the base plate 2. In the positioning mechanism 40, the insertion portion may be formed in the base plate 2, and the second projecting portion may be formed in either the substrate 7 or the bus bar 6.

The arrangement and shape of each member illustrated in FIG. 1 are merely examples, and can be appropriately changed without departing from the gist of the present disclosure.

### REFERENCE SIGNS LIST

1 Fixation structure
2 Base plate (Structure)
3A First core (First magnetic component)
3B Second core (Second magnetic component)
4 Spacer member
6 Bus bar (Another component)
7 Substrate (Another component)
28 Projecting portion (Second projecting portion)
30A, 30B Positioning mechanism (First positioning mechanism)
31A, 31B Projecting portion (First projecting portion)
32A, 32B Insertion portion
40 Positioning mechanism (Second positioning mechanism)
100 Electronic unit
GP1 Gap.

1. A fixation structure comprising:
a structure;
a first magnetic component and a second magnetic component fixed to the structure and facing each other in a first direction; and
a spacer member disposed between the first magnetic component and the second magnetic component, wherein
the spacer member and the structure are spaced away from each other.

2. The fixation structure according to claim 1, further comprising a first positioning mechanism configured to position the spacer member with respect to the structure in a direction orthogonal to the first direction.

3. The fixation structure according to claim 2, wherein
the first positioning mechanism includes:
a first projecting portion formed on one of the spacer member and the structure and extending in the first direction; and
an insertion portion formed on the other of the spacer member and the structure and for inserting the first projecting portion in the insertion portion.

4. The fixation structure according to claim 2, further comprising a second positioning mechanism configured to position another component other than the first magnetic component and the second magnetic component and the spacer member.

5. The fixation structure according to claim 1, wherein
the structure includes a second projecting portion projecting in the first direction toward the spacer member, and
a gap between the spacer member and the structure is formed between the second projecting portion and the spacer member.

6. An electronic unit comprising the fixation structure according to claim 1.
